(19) United States
(12) Patent Application Publication
(10) Pub. No.: US 2013/0334880 A1
(43) Pub. Date: Dec. 19, 2013

(54) Digital Electrical Routing Control System for Use with Electrical Storage Systems and Conventional and Alternative Energy Sources

(71) Applicant: Olivier L. Jerphagnon, Foster City, CA (US)

(72) Inventor: Olivier L. Jerphagnon, Foster City, CA (US)

(21) Appl. No.: 13/844,605

(22) Filed: Mar. 15, 2013

Related U.S. Application Data
(60) Provisional application No. 61/646,015, filed on May 11, 2012.
(60) Provisional application No. 61/650,484, filed on May 23, 2012.
(60) Provisional application No. 61/694,907, filed on Aug. 30, 2012.

(51) Int. Cl. H02J 4/00; G01R 31/36

(52) U.S. Cl. CPC H02J 4/00; G01R 31/36
USPC 307/23; 324/427

(57) ABSTRACT

Described is a digital electrical routing control system for use with electrical storage systems and conventional and alternative energy sources, and methods of using the same. In one aspect is described a method of determining an amount of energy used by a load using a computer, with the energy being provided from a first battery and a second battery, and with other energy being supplied to charge the first battery and the second battery, the method comprising the steps of: initiating, using the computer, charging of the first battery with the other energy while the second battery is being drained by connection to the load; initiating, using the computer, charging of the second battery with the other energy while the first battery is being drained by connection to the load; and detecting, using the computer, an amount of energy consumed during an interval of time based upon an amount of charging of the first battery and the second battery during the interval of time.

### RELATED APPLICATIONS

This application claims priority to U.S. Provisional Application Nos. 61/646,015 filed May 11, 2012, 61/650,484 filed May 23, 2012, and 61/694,907 filed Aug. 30, 2012, which applications are expressly incorporated by reference herein and is related to U.S. patent application Ser. No. 13/844,648 entitled PEER-TO-PEER TRANSACTION AND MOBILE ENERGY SERVICE being filed concurrently with this application on Mar. 15, 2013, which application is expressly incorporated by reference herein.

### FIELD OF THE RELATED ART

Described is a digital electrical routing control system for use with electrical storage systems and conventional and alternative energy sources.

### BACKGROUND OF THE RELATED ART

Conventional grid-based electrical power distribution is well established. Grid-based power relies on large-scale generators and power meters at the end of the distribution network in order to measure the electricity used by a customer and be able to charge for it.

Power obtained by alternative energy sources is also proliferating significantly. Power produced by alternative means, such as solar and wind, for example, is intermittent. It does not provide a reliable energy service on its own compared to conventional grid-based power systems. Moreover, it isn't easily accommodated by the conventional grid-based power systems that currently exist.

Alternative energy sources can also be deployed at customer premises, beyond the meter, such as solar roof installations or urban wind turbines. Most solar or wind power installations on the customer side of the meter are tied to the grid. When the load of a building is more than what the solar or wind source provides at any given time, the conventional grid-based electrical power provides the difference. When the load of a building is less than what the solar or wind source provides at any given time, the conventional grid-based electrical power absorbs the flux of electricity to a certain limit The customer does not have to deal with the intermittency of the renewable energy source. The utility managing the conventional grid-based electrical power deals with it. The utility takes into account the energy created at the customer location using two power meters or one bi-directional power meter.

Also required is what is known as a grid-tie inverter, which transforms the DCpower of most alternative energy sources into the AC power that is required by the conventional grid-based power systems. In a time of blackout, however, grid-tie inverters become tripped into an off position, as they no longer receive the oscillating signal from the AC power of the grid that indicates presence of AC power. When tripped off, however, the alternative energy sources to which they are attached also become disconnected from the customer who desires to use the power generated thereby.

### SUMMARY

Described is a digital electrical routing control system for use with electrical storage systems and conventional and alternative energy sources, and methods of using the same.

In one aspect is described a method of determining an amount of energy used by a load using a computer, with the energy being provided from a first battery and a second battery, and with other energy being supplied to charge the first battery and the second battery, the method comprising the steps of: initiating, using the computer, charging of the first battery with the other energy while the second battery is being drained by connection to the load; initiating, using the computer, charging of the second battery with the other energy while the first battery is being drained by connection to the load; and detecting, using the computer, an amount of energy consumed during an interval of time based upon an amount of charging of the first battery and the second battery during the interval of time.

In another aspect is described apparatus for routing energy from an DC energy source to a load, using an array of batteries that include at least a first battery and a second battery, the apparatus comprising:

a DC switch, the DC switch including:
a DC input;
a DC output;
a plurality of DC charging inputs/outputs for connection to the array of batteries, including the first battery and the second battery; and
a DC switch matrix for selectively coupling between the DC input, the DC output, the converter input, the converter output, and the plurality of DC charging inputs/outputs; and

a controller that includes a processor and software executable by the processor, the controller controlling the DC switch matrix state, thereby permitting: charging of the first battery while the second battery is being drained by connection to the load; and charging of the second battery while the first battery is being drained by connection to the load.

In a further aspect is described an apparatus for routing energy from a AC energy source to at least one load, using an array of batteries that include at least a first battery and a second battery, the apparatus comprising:

a DC switch, the DC switch including:
a DC input ;
a DC output;
an AC to DC converter input/output;
a DC/AC converter input/output;
a plurality of DC charging inputs/outputs for connection to the array of batteries, including the first battery and the second battery; and
a DC switch matrix for selectively coupling between the DC input, the DC output, the AC to DC converter input/output, the DC/AC converter input/output, and the plurality of DC charging inputs/outputs;

an AC switch, the AC switch including:
an AC input;
an AC output;
an AC to DC converter for converting alternating current to direct current;
a DC to AC converter for converting direct current to alternating current; and
an AC switch matrix selectively coupling between the AC input, the AC output, the AC to DC converter, and the DC to AC converter; and
a controller that includes a processor and software executable by the processor, the controller controlling a DC switch matrix state and an AC switch matrix, thereby permitting: charging of the first battery while the second battery is being drained by connection to the load; charging of the second battery while the first battery is being drained by connection to the load; and wherein the controller further detects an amount of energy consumed during an interval of time based upon the state of charge of the discharging battery at the start and the end of the interval of time; and wherein the controller further detects an amount of energy provided during an interval of time based upon the state of charge of the charging battery at the start and the interval of time.

### IN THE DRAWINGS

FIG. 1 illustrates an embodiment of a digital electrical routing control system with a configuration of one source/supply to one load.

FIG. 2 illustrates another embodiment of a digital electrical routing control system with a configuration of multiple sources and a load.

FIG. 3 illustrates another embodiment of a digital electrical routing control system with a configuration of one source and multiple loads.

FIG. 4 illustrates a further embodiment of a digital electrical routing control system with a configuration of a local source and multiple loads.

FIG. 5 illustrates a further embodiment of a digital electrical routing control system with a configuration of multiple sources and multiple loads.

FIG. 6 illustrates an illustrative specific embodiment of a digital electrical routing control system with a configuration of three sources and three loads.

FIG. 7 illustrates a more complex embodiment configuration of a digital electrical routing control system.

FIG. 8 illustrates a typical load profile.

FIG. 9 illustrates the energy provided to support the load profile shown in FIG. 8.

FIGS. 10A-10B illustrate load storage requirements for a home.

FIG. 11 illustrates energy usage and load shifting.

FIG. 12 illustrates energy usage by leveraging an elastic load.

FIG. 13 illustrates reduction in variation of state of charge.

FIG. 14 illustrates an exemplary reduction in variation of state of charge using four battery packs.

FIG. 15 illustrates a transformer down method using the digital electrical routing control system.

FIG. 16 illustrates a transformer up method using the digital electrical routing control system.

FIG. 17(a-c) illustrate a back-up method.

FIG. 18 illustrates a battery pack equalization method using the digital electrical routing control system.

FIG. 19 shows one embodiment of the digital electrical routing control system used to create a DC energy meter and power average apparatus.

FIG. 20 shows one embodiment of the digital electrical routing control system used to create a DC energy router apparatus.

FIG. 21-a shows one embodiment of the digital electrical routing control system used to create an AC energy meter and power average apparatus.

FIG. 21-b shows another embodiment of the digital electrical routing control system used to create an AC energy meter and back-up apparatus.

FIG. 21-c shows another embodiment of the digital electrical routing control system used to create an AC energy meter and long-term storage apparatus.

FIG. 22 shows one embodiment of the digital electrical routing control system used to create an AC-DC energy router.

FIG. 23 shows one embodiment of the digital electrical routing control system used to create an RX/TX AC-DC energy router.

FIG. 24 illustrates control flow at fixed intervals.

FIG. 25 illustrates both a DC connectivity matrix for usage with a DC switcher, as well as AC connectivity matrix for usage with an AC switcher.

FIG. 26 illustrates control flow at fixed intervals between the digital electrical routing control system and the battery packs in the battery array.

FIG. 27A illustrates the state of charge matrix.

FIG. 27B illustrates the matrices [R] (T) that sets the rates of charge or discharge for each battery at each time interval T.

FIG. 28A illustrates the control flow to add a new battery pack to array using the digital electrical routing control system.

FIG. 28B illustrates the control flow where the digital electrical routing control system with new information provided from the battery pack.

FIG. 29 illustrates the control flow between server and the digital electrical routing control system at regular times to retrieve energy usage data and provide forecast data.

FIG. 30A illustrates a usage matrix.

FIG. 30B illustrates a forecast matrix.

FIGS. 31A-B illustrates conventional implementations.

FIG. 32 shows flexible and intermittent energy sources provided over time to the digital electrical routing control system.

FIGS. 33 and 34 each illustrate energy services provided with hard and soft control by the digital electrical routing control system, respectively.

FIG. 35 illustrates a flowchart of normal operation of the digital electrical routing control system.

FIG. 36 illustrates a flowchart showing grid black-out operation of the digital electrical routing control system.

FIG. 37 illustrates a flowchart showing new tariff schedule operation of the digital electrical routing control system.

FIG. 38A illustrates an embodiment of energy routers exchanging energy without affecting the grid.

FIG. 38B illustrated another embodiment of a peer-to-peer energy transaction technique.

FIG. 39 illustrates a flowchart of commands to coordinate the charge and discharge events of power on the grid over a period of time.

In FIG. 40 illustrates an embodiment of a peer-to-peer energy transaction technique that leverages wholesale markets to extend service across local grids connected by a utility grid that does not support peer-to-peer energy transactions.

FIG. 41 shows another embodiment using a secure mobile payment application to provide for an exchange of energy.

### DETAILED DESCRIPTION OF THE PREFERRED EMBODIMENTS

Described herein is a digital electrical routing control system for use with electrical storage systems and conventional and alternative energy sources.

In a preferred embodiment, an array of two or more batteries are used to de-couple the load(s) and energy source(s), and the digital electrical routing control system provides the functionality to ensure correct energy flow between various energy sources and loads, through the batteries that also store electrical power obtained from the various energy sources. The digital electrical routing control system described herein does not require a meter or an analog feedback-loop, as will be seen from the descriptions hereafter.

From a functional perspective, the digital electrical routing control system described herein allows for the connections among batteries, load(s), and source(s) to be updated at regular and slow intervals, 15 minutes or more, for instance. This period of time can be used to fine up solar energy to provide stable electricity, to provide back-up power, to average a variable load, to reduce the constraint on a source, or to provide an alternative to sub-metering in a multi-dwelling location attached to one meter.

Thanks to the digital electrical control system, functions can be programmed in software and are not tied to the analog nature of the power system. The functions referenced herein can be reprogrammed at will. In addition, the array of batteries provides a buffer memory feature. This provides a base to use stochastic models to develop software algorithms to control the digital electrical routing system.

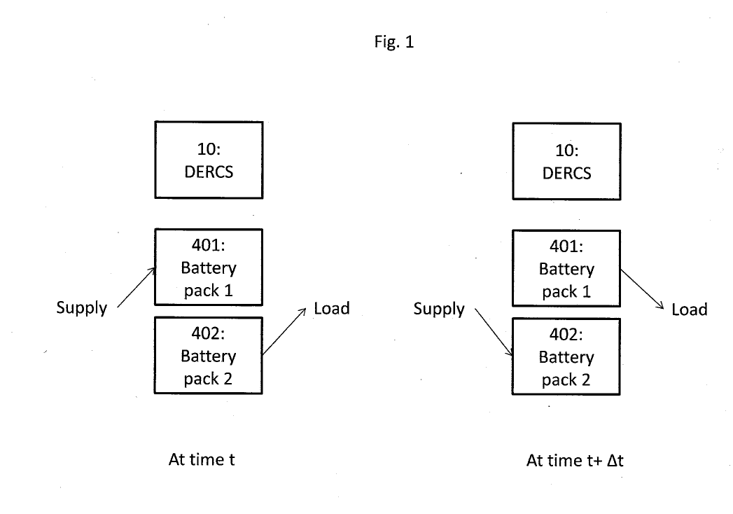

FIG. 1 illustrates a simple case, a one-by-one configuration, where a source/supply of energy is connected to one battery 401 and a load is connected to a second battery 402. After a predetermined interval, such as 15 minutes, battery 401 is connected to the load and battery 402 is connected to the source/supply. At each interval, the switching alternates, as controlled by the digital electrical routing control system 10, described further hereinafter.

If the source/supply is intermittent, such as solar panels or wind, and the load is an inelastic load, such as a home, the digital electrical routing control system 10 shown in FIG. 1 can maintain power to the service/load because the charging battery is averaging the intermittent power over a period of time. The control system can determine the energy provide by the supply without requiring a meter, as described further hereinafter. During the short switching events, power can be maintained to the load with capacitors that hold the voltage and current for a brief period of time.

If the source/supply is stable, such as the conventional utility grid, the digital electrical routing control system 10 shown in FIG. 1 can average a variable load (e.g., high-duty equipment like a high-voltage-air-conditioning system or a water pump), and draw energy from the grid at a fixed rates. Undesirable harmonics generated by the motor of the high-duty equipment are shielded from the conventional utility grid.

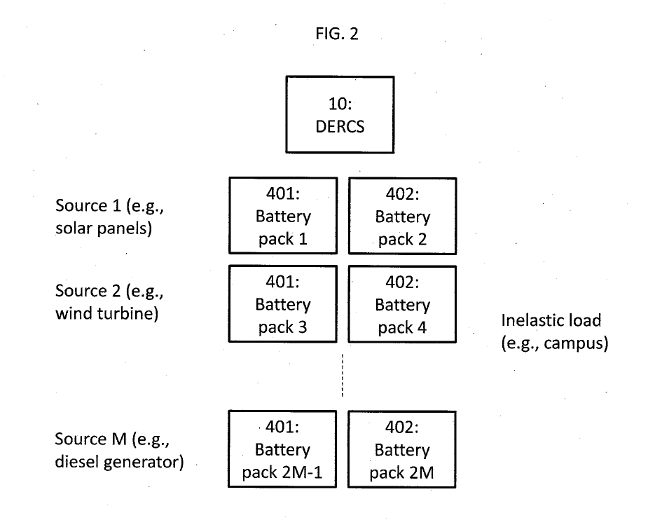

In another arrangement of an M-by-one configuration shown in FIG. 2, an array of 2M batteries is connected to multiple sources of renewable energy, and an inelastic load. The batteries store energy when the renewable sources are available (e.g., daylight for solar panels) or when it is cheaper (e.g., off-peak hours for the grid). The digital electrical routing control system 10 controls these various multiple sources, and when the loads are connected to them, to reduce the cost of electricity from the grid, optimize the usage of renewable energy, reduce pollution, or make sure that there is always enough energy to support the load. Historical data, weather data, tariff schedules and forecasting techniques can be leveraged. In particular the digital electrical routing control system 10 can use the data to compute the states of the batteries at regular interval to provide reliable power. In particular, stochastic models can be used to mitigate errors in forecasting data as time passes without impacting service.

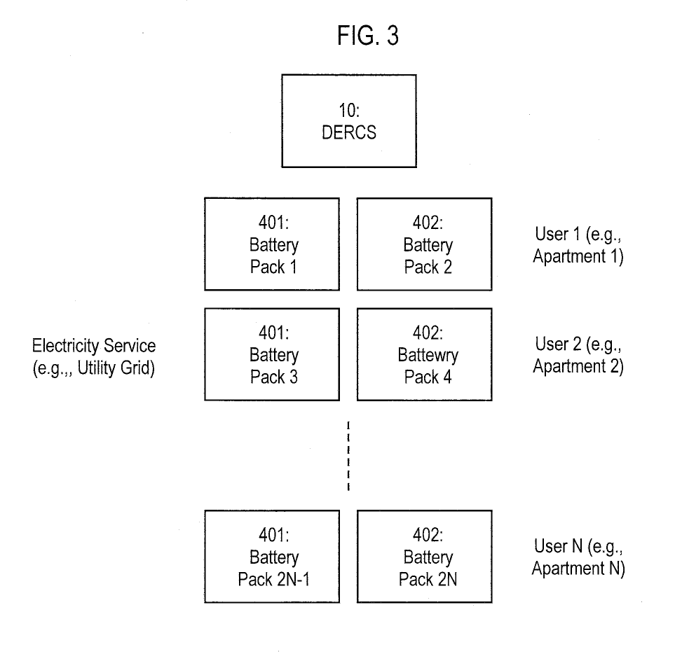

In a further arrangement shown in FIG. 3, a one-by-2N configuration has an array of 2N batteries that is connected to the grid and N users, such as several apartments in one multi-dwelling residence. By alternating two groups of N batteries between the grid and the N loads, the digital electrical routing control system 10 can alleviate the need for sub-meters, which can be expensive. The energy consumed by each user is reported by the management system of each battery pack at the end of each discharging period. The internal system is often proprietary and always analog in nature. It does not have to be disclosed to digital electrical routing control system 10. Only digital data are shared. In a grid environment (as shown), only one meter is connected to the grid, that being the meter that supplies the overall energy to the battery pack array. The digital electrical routing control system 10 can track the individual usage of the various users.

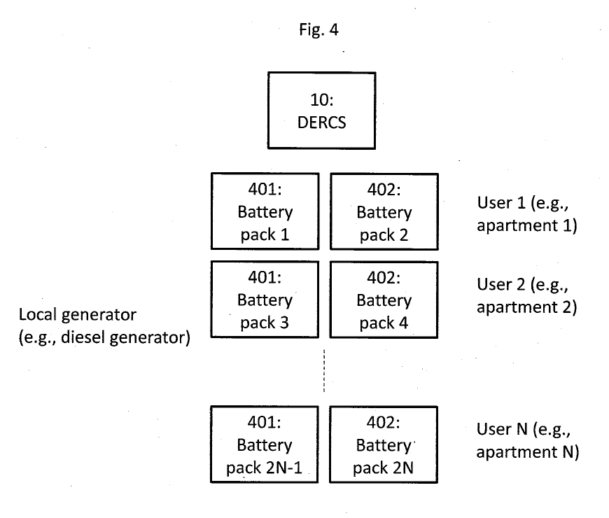

If off-grid energy is provided, then an adaptation as shown in FIG. 4 can be included. This configuration, which can be used in rural areas, as well as in other countries that have sparse on-grid power, allows for other off-grid type electrical power sources to be connected, such as alternative energy sources like wind and solar, as well as diesel generators as shown. As in the previous embodiment of FIG. 3, the digital electrical routing control system 10 can track the individual usage of the various users, through the discharge of the battery packs being reported. This allows billing of users without having to place meters in homes. The digital electrical routing control system 10 can also store that usage for a period of time locally, such as a week or a month, and then be configured to send bills of the users, based on the power consumption and established rates for the power or alternatively report the usage to a central billing system, which can perform this same function. As described further hereinafter, whether performed at the digital electrical routing control system 10 or the central billing system, the bills can then be sent by cell phones or email, and service can be remotely terminated on one particular line if user does not pay bill.

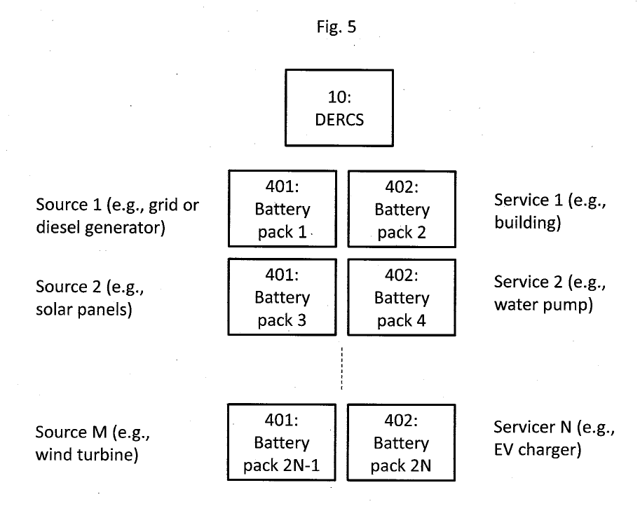

FIG. 5 illustrates an M-by-N configuration where an array of M+N or more batteries aggregate energy from M sources and support N different services, all of which are controlled by the digital electrical routing control system 10. Sources can be a flexible source like the grid or a diesel generator. Sources can be intermittent like solar panels or wind turbines. Similarly, services can be inelastic like the load of light bulbs or appliances because customers expect light to be on when they turn the switch on, or they expect an appliance to work when they use it. Services can be elastic like water pumps or electric vehicles because it does not matter exactly when energy is provided as long as it happens within an appropriate window, overnight for a vehicle or a day for a water pump, all of which can be controlled and monitored by the digital electrical routing control system 10.

Traditionally, different services like electricity for a home and electricity for a water pump are supported by different meters. This is particularly the case when they require different voltage and currents, a lower power single-phase line and a higher-power three-phase line for instance. The “by-N” configuration can support the two services, even if only using only one source, which can be, for example, a lower power line when a local source of energy like solar is available.

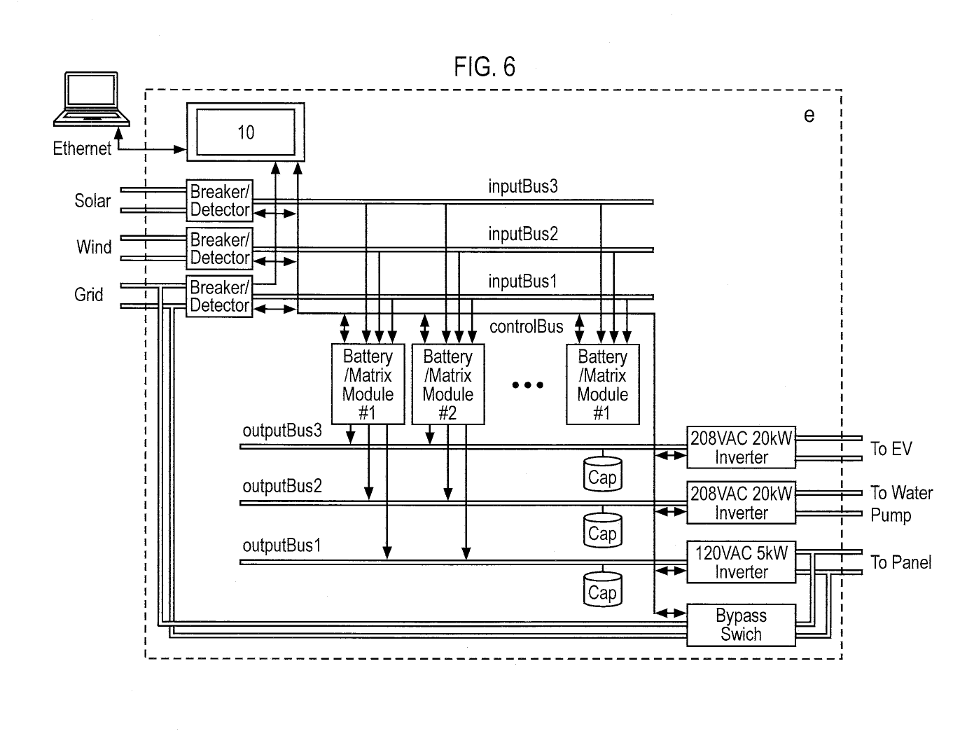

FIG. 6 illustrates a 3-by-3 system of 3 sources and 3 loads. In this embodiment digital electrical routing control system 10 is configured to control the battery packs, with the switching function integrated with the battery packs. A three level buss interconnects the batteries with the various sources and loads.

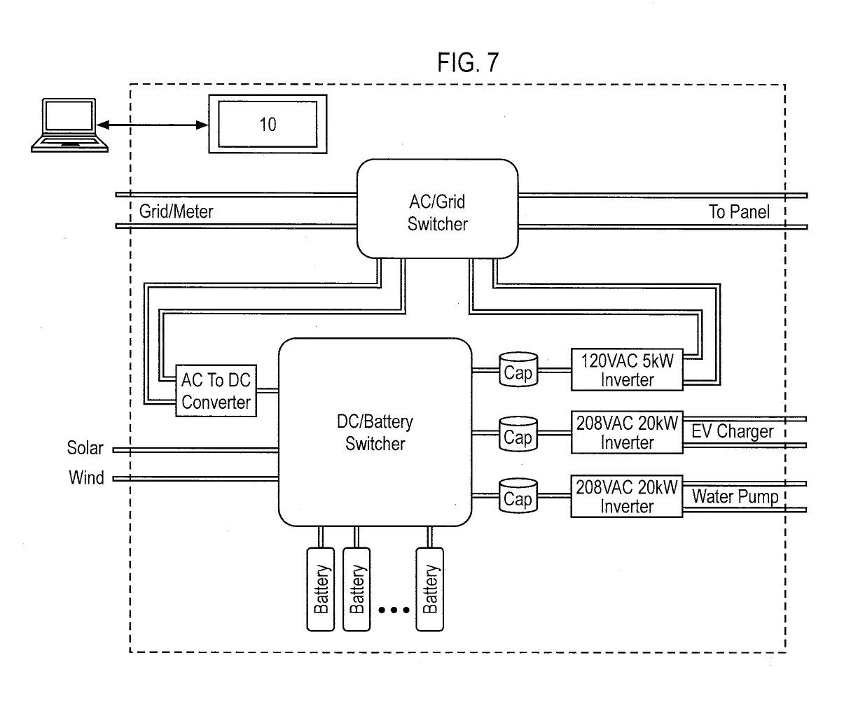

Another more complex configuration of the digital electrical routing control system 10 is shown in FIG. 7. In this embodiment, the digital electrical routing control system 10 controls a DC switcher, which operates to change the connectivity between the sources, services and the batteries. The connectivity can be represented by a mathematical matrix and can be updated at regular interval, 15 minutes or more, as described hereinafter. The batteries include their own battery management system, as described previously. Advantageously, if such batteries have their proprietary control, that need not be shared with the digital electrical routing control system 10, as the digital electrical routing control system 10 controls what batteries are charged and what batteries are discharged at any given time. This enables the digital electrical routing control system 10 to use software algorithms that are decoupled from the analog nature of the batteries. In one embodiment, the batteries are from different vendors.

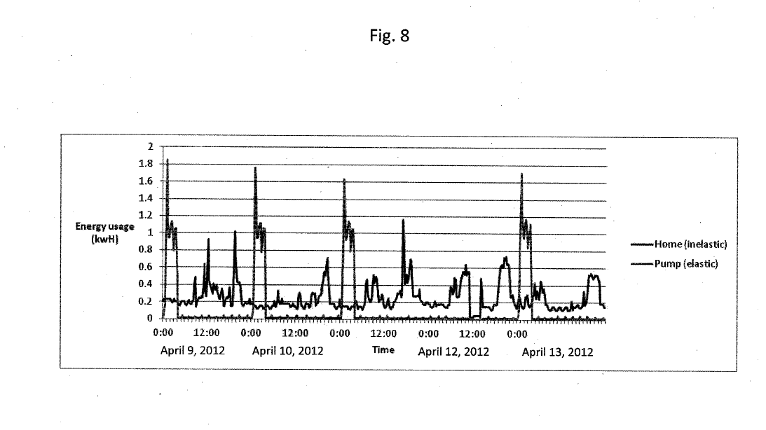

As example of an application in which the digital electrical routing control system 10 can be used, we consider the example of a household with energy needs for the building and for the outside water pumps. A typical load profile is represented for 5 consecutive days in a week in April 2012, as shown in FIG. 8. The load of the home is inelastic and the load of the water pump is elastic within a couple of days.

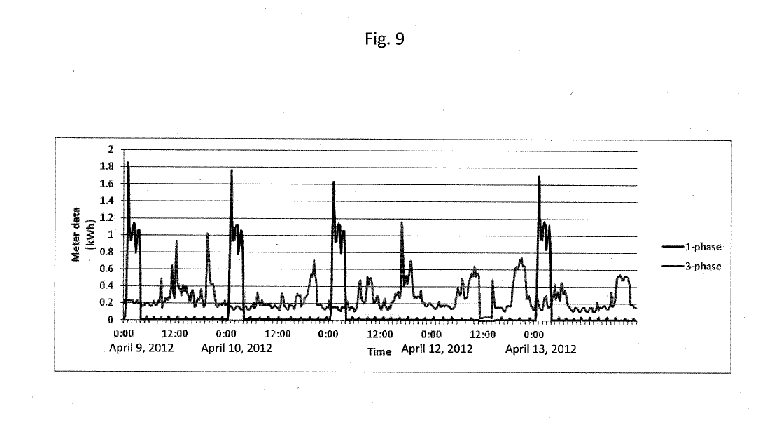

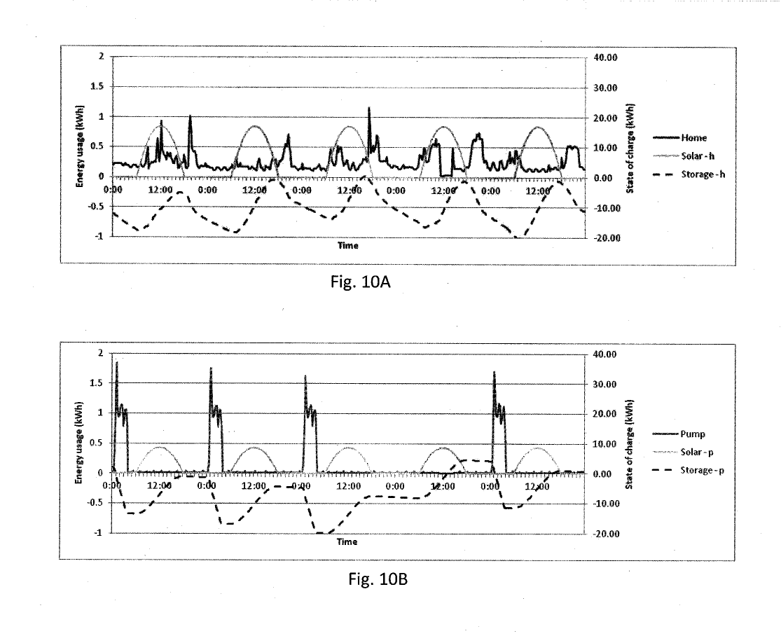

The energy needs of this household are supported by two different lines as shown in FIG. 9 connected to the utility's distribution network. The building is connected to a single-phase service and monitored by a meter. The water pump is connected to a three-phase service and monitored by a separate meter.

The price of electricity for the single-phase line depends on the quantity consumed as well as time of day. The peak hours are 1 to 7 pm, and the cost of electricity goes up beyond a baseline set for a month. The three-phase line has a higher and flat fee per kWh consumed, independently of the time of day or the quantity used. A 2×2 digital electrical routing control system 10, in conjunction with a local solar installation, can reduce the number of lines from two to one, and use the cheaper tariff during off-peak hours.

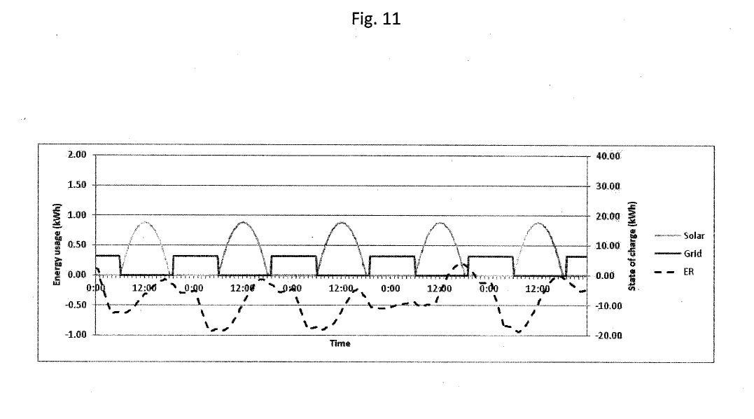

The solar installation can also be used to reduce the cost of electricity. A 4.2 kW installation would be needed to cover the needs of the home, and a 2.3 kW installation for the water pump. This can be done with net metering (grid manages the produced energy) or with on-site storage. The home would require at least 21 kWh of energy storage as shown in FIG. 10A, and the water pump at least 25 kWh of energy storage as shown in FIG. 10B. Instead, one solar installation can be used for both the home and the water pump with the 2-by-2 digital electrical routing control system 10. This has the advantage to reduce the solar installation and the amount of energy storage. In particular, the ER can perform energy arbitrage. As a matter of fact, electricity is cheap for the residential line below a threshold (350 kWh). Prices modestly go up to a second threshold (450 kWh) and are higher than the three-phase service for a third threshold (700 kWh). As a result the solar energy is used to shift the load from peak hours to off-peak hours, as shown by FIG. 11. The solar installation can be reduced to 4.7 kW as opposed to 6.7 kW in total for two separate installations. The energy storage requirement is reduced from 46 kWh to 23 kWH.

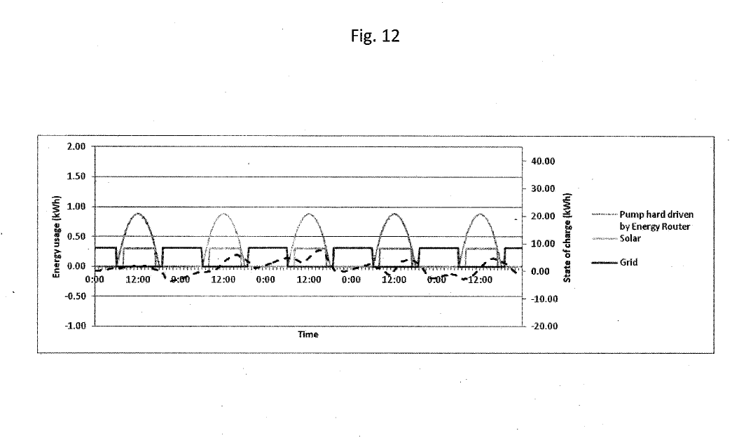

The digital electrical routing control system 10 can further reduce the amount of energy storage, or extend the lifetime of the batteries by leveraging the elastic load. In this case, the digital electrical routing control system 10 leverages when to turn on or off the water pump as shown in FIG. 12. The variation in state of charge is reduced by 50% to less than 12 kWh. This can be used to reduce the storage size requirement by half or to extend the life-cycle of the storage by a factor of two. This does not require communication between the digital electrical routing control system 10 and the pump because the digital electrical routing control system 10 can force the water to turn off although it wants to pump water (“hard control”). In the case where the digital electrical routing control system 10 can control the water pump, it can further reduce the amount of energy storage.

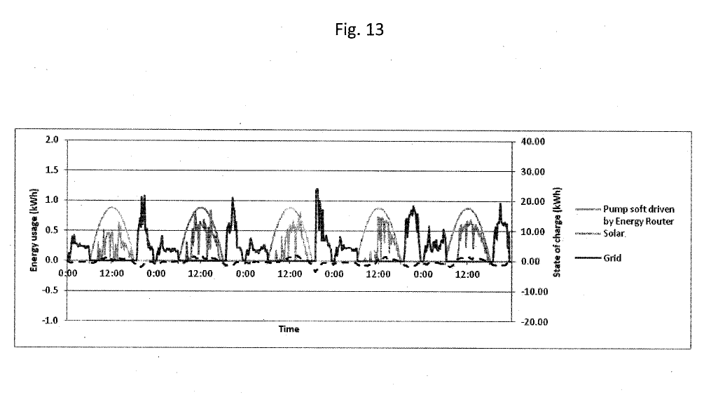

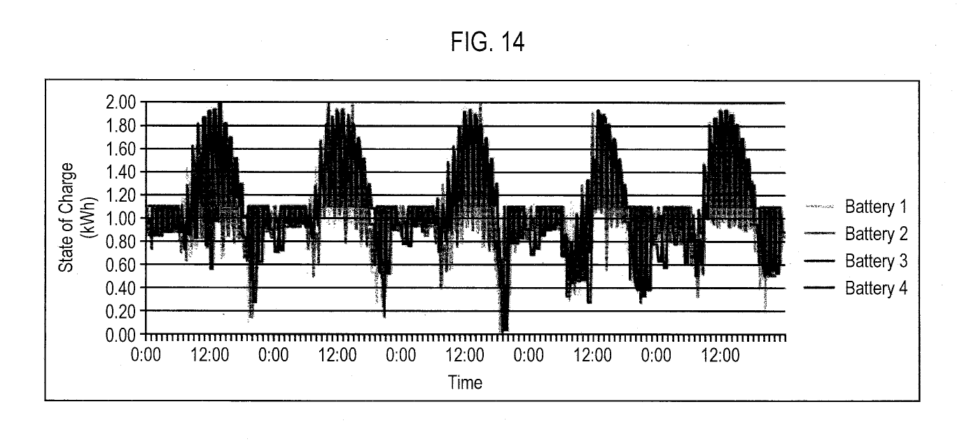

The digital electrical routing control system 10 can also reduce the variation in state of charge of the storage batteries. In this example, the variation in state of charge is reduced by 65% to less than 8 kWh, as shown in FIG. 13. This can be used to reduce the storage size requirement of battery packs within the system, or extend the lifecycle of battery packs within the system. In this example, the storage is composed of four battery packs of more, and the state of charge for each is represented in FIG. 14. The state of charge for each battery pack is maintained within 2 kWh. This does not require any feedback loop, but instead the digital electrical routing control system 10 computes a new connectivity matrix every interval, such as every 15 minutes. As also described hereinafter the digital electrical routing control system 10 sends energy usage data to cloud server every 24 hours, and retrieve forecast data from the server 500.

In light of the above usage examples, various power control methods that can be performed by the digital electrical routing control system 10 will now be described.

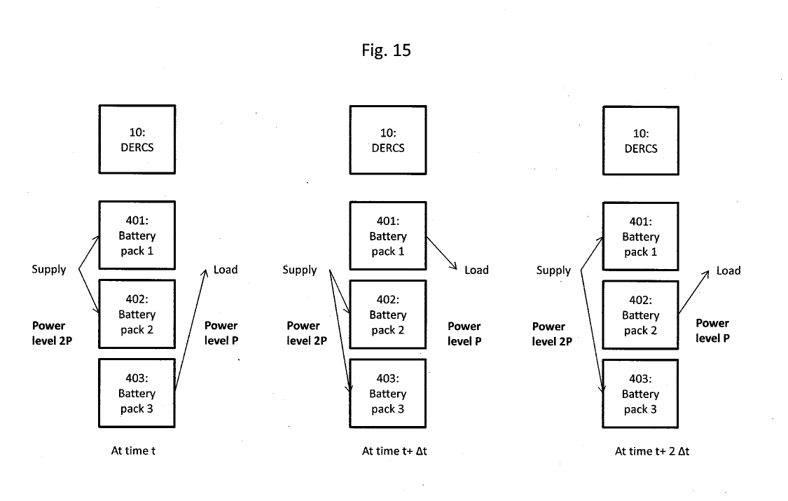

FIG. 15 illustrates a transformer down method in which power is reduced from 2P at the input to P at the output using the digital electrical routing control system 10. The transformer ratio of ½ is supported by 3 battery backs shown as battery packs 401, 402 and 403. In particular, while two battery packs are always being charged at 2P in each of the three time periods shown, a different battery pack is being discharged at P.

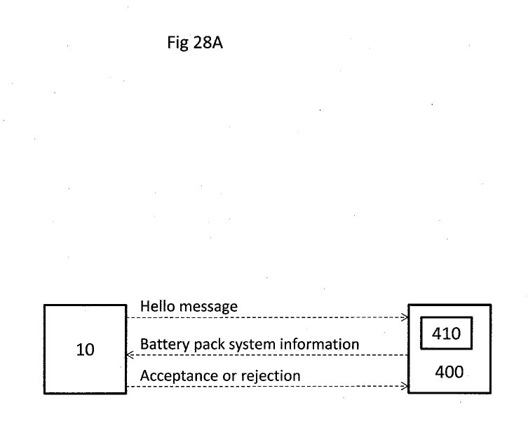

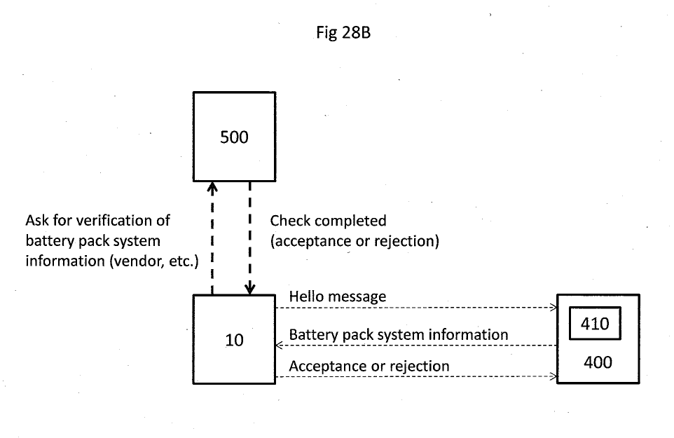

Different discrete power ratios can be supported with a higher number of battery packs. Four battery packs can support a ratio of ½ or ⅓, five battery packs can support a ratio of ½, ⅓ or ⅕, etc. Also, the resolution of the transformer ration can be can be improved by adjusting the charge and discharge rates. As a matter of fact, battery packs typically support a range of charge rates (0.5 C, 0.6C, etc) and a range of discharge rates (0.5C, 0.6C, etc) in relation to the capacity of the battery pack capacity referred as C. For instance if the charge rate is increased and the discharge rate is decreased, the transformer ratio goes. down. If the charge rate is decreased and the discharge rate is increased, then the transformer ration goes up. The charge and discharge rates of the battery packs is set by the digital electrical routing control system 10 at regular intervals, such as every 15 minutes. When the battery packs are installed for the first time, they inform the digital electrical routing control system 10 of the range of charge and discharge rates that they support. FIG. 28 describes an example of control mechanism when a battery pack 410 is connected to the digital electrical routing control system 10. Additional information such as battery pack and model can be checked by a server 500 communicating with 10.

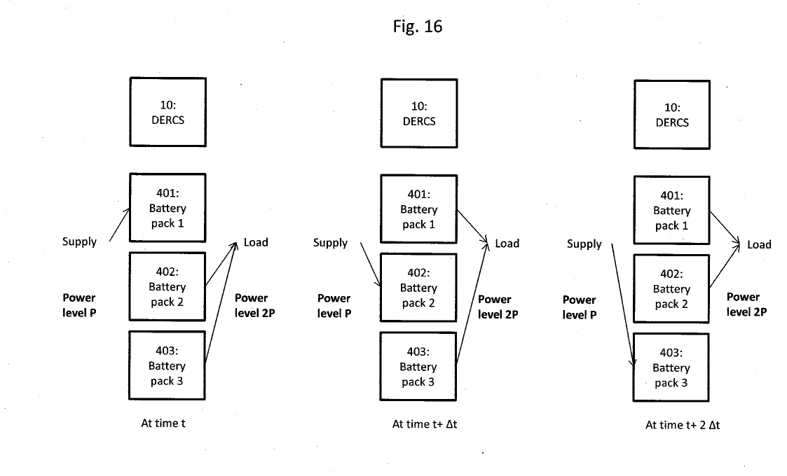

FIG. 16 illustrates a transformer up method in which power is increased from P to 2P using the digital electrical routing control system 10. The transformer ratio of ½ is supported by 3 battery backs shown as battery packs 401, 402 and 403. As for the transformer down method, different ratios can be supported with a larger number of battery packs. As for the transformer down method, the ration can more finely adjusted by varying the charge and discharge rates that the battery packs can support.

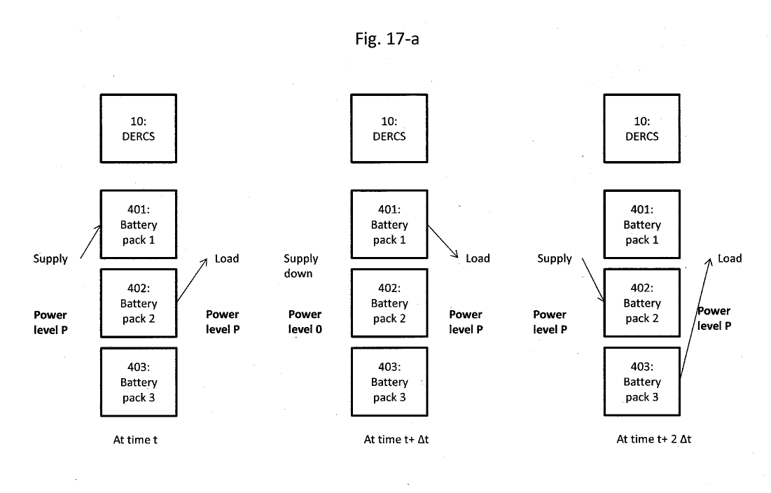

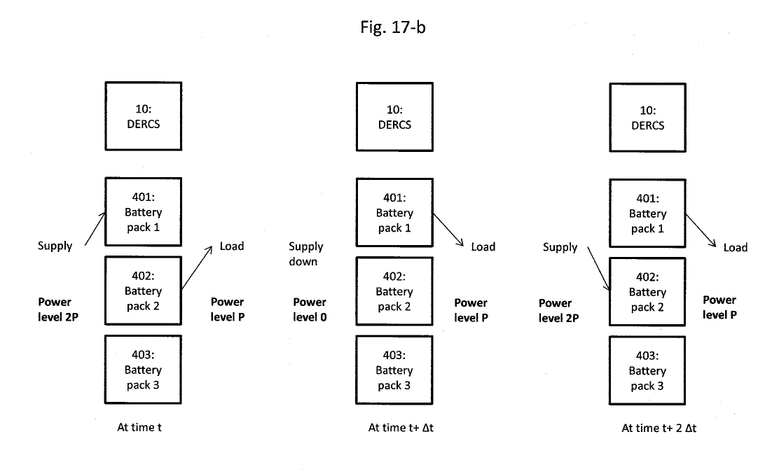

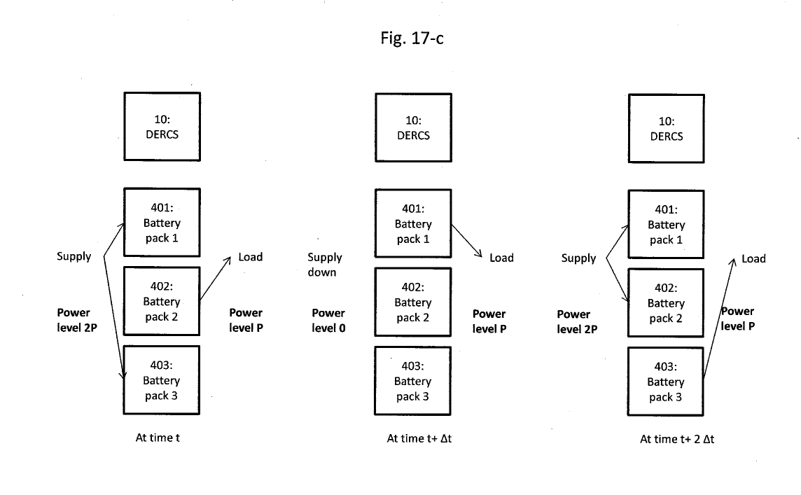

FIG. 17-aillustrates a back-up method in which power service is maintained at the output even as power is momentarily lost at the input. As shown, at time t+Δt, no charging is occurring from the source, and the previously charged battery 401 is discharging, and at time at time t+2Δt, discharging is occurring from a stand-by source 403. An alternative way to implement back-up is to store more energy during a number of cycles and to provide back-up at a later interval using the digital electrical routing control system 10. This can be done by charging the battery packs at a higher rate than they are discharged as described in FIG. 17b. It can also be done by charging more battery packs than there are being discharged as described in FIG. 17-c. Because two battery packs are charged and only one battery discharged at each interval, the temporarily loss of power at the input does not affect the power at the output.

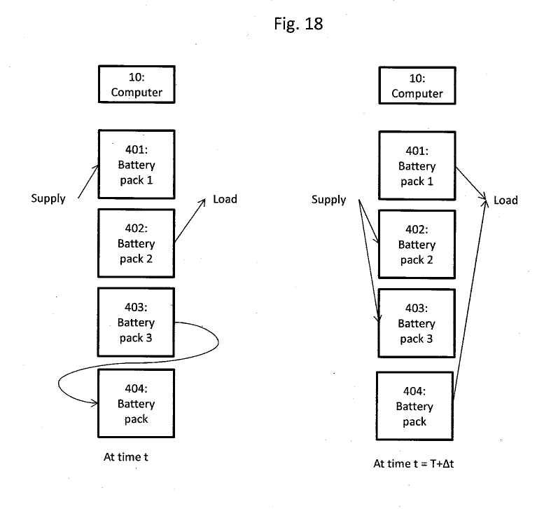

FIG. 18 illustrates a battery pack equalization method using the digital electrical routing control system 10. In particular, Battery pack 403 charges battery pack 404 during interval Δt to balance their state of charge.

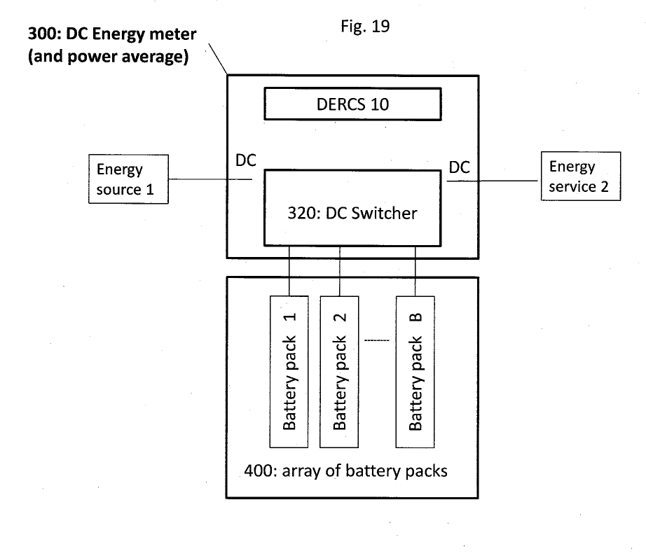

FIG. 19 shows one embodiment of the digital electrical routing control system 10 used to create a DC energy meter and power average apparatus 300. The energy meter and power average apparatus 300, in addition to the, digital electrical routing control system 10 that is configured to perform these functions, also contains a DC switcher 320 to which is connected the energy source and the energy service, as well as an array of battery packs 400. The energy metering is performed by reading the discharge of the battery packs being used for the source at the defined intervals, in order to determine energy usage. The power averaging is performed by the charging battery that charges a varying level of power but reports the average power derived from the total energy stored during the interval of time and the duration of the interval.

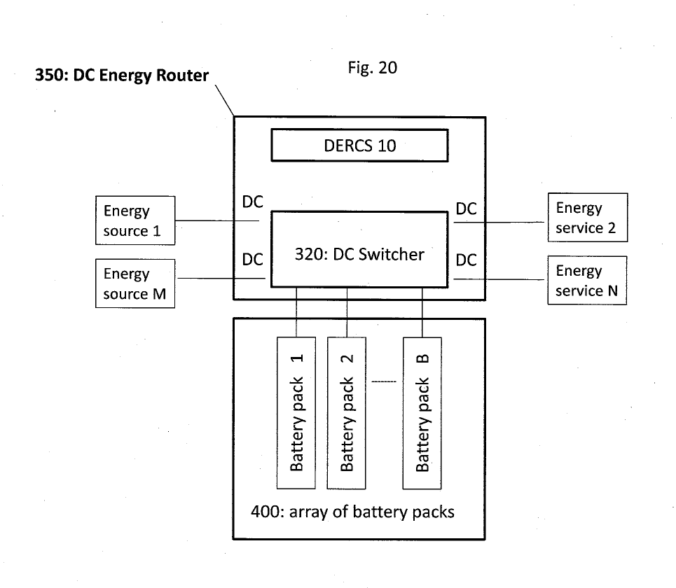

FIG. 20 shows one embodiment of the digital electrical routing control system 10 used to create a DC energy router apparatus 350. The DC energy router apparatus 350 can perform the metering and power averaging functions described with respect to the energy meter and power average apparatus 300, as well as controlling switching of DC supply power being input, as well as DC power being output. In addition to the digital electrical routing control system 10 that is configured to perform these functions, the DC energy router apparatus 350 also contains a DC switcher 320 to which is connected the multiple energy sources and the multiple energy services, as well as the array of battery packs 400. Due to the multiple energy sources and the multiple energy services, in addition to controlling metering and power averaging, the digital electrical routing control system 10 also controls routing of energy from these multiple energy sources and services.

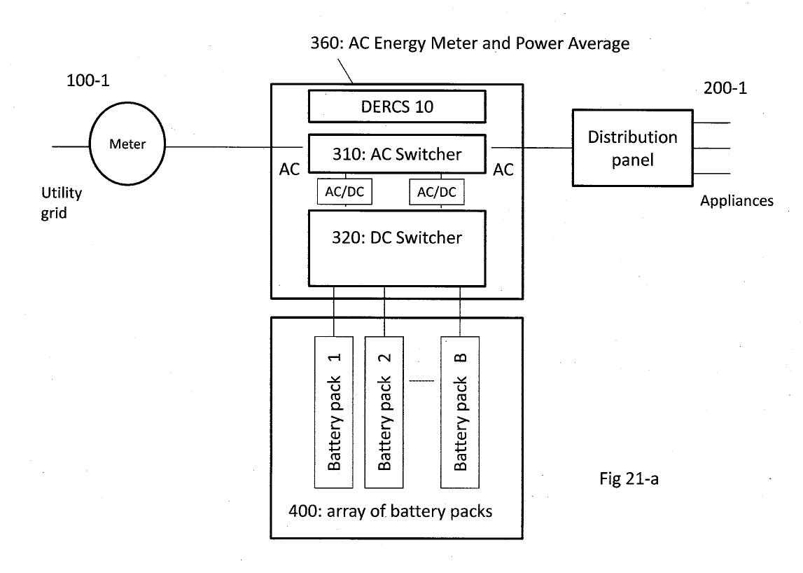

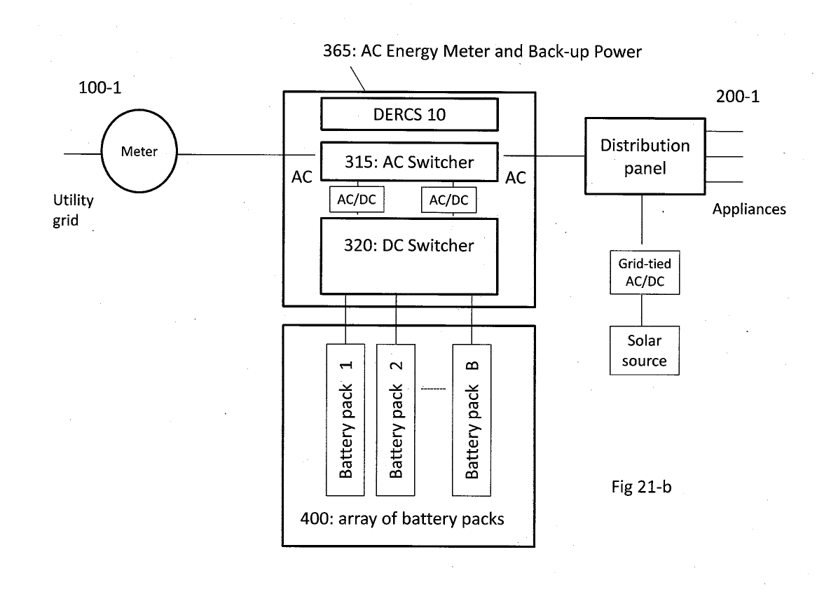

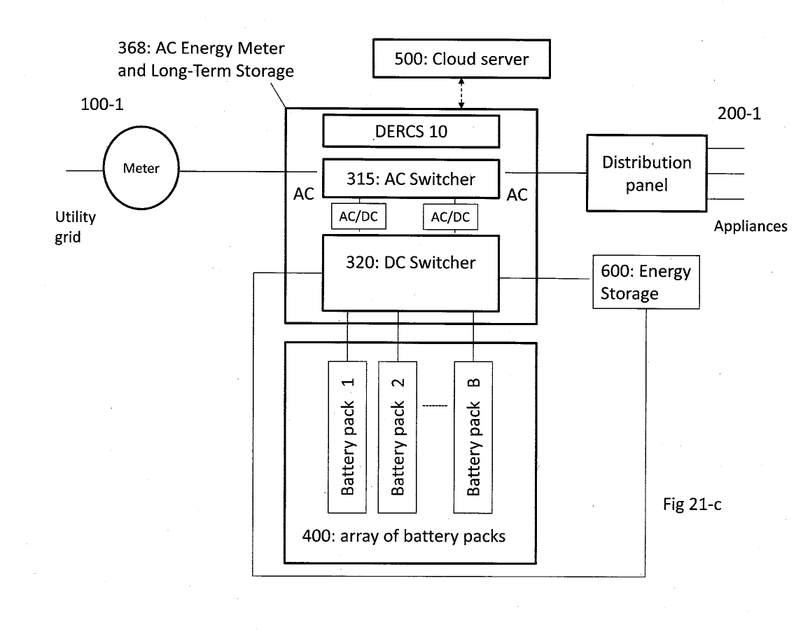

FIG. 21A shows one embodiment of the digital electrical routing control system 10 configured for and used to create an AC energy meter and power average apparatus 360. The AC energy meter and power average apparatus 360 can perform the metering and power averaging functions described with respect to the energy meter and power average apparatus 300, though for AC grid power rather than DC power. As such, the AC energy meter and power average apparatus 360 is connected between grid power and the distribution panel, to which appliances and outlets are connected, and also includes an AC switcher disposed between the meter and the distribution panel, and which is also connected to the DC switcher/converter via an=AC-DC converter, as well as a DC-AC converter, thereby allowing grid power to be used to charge the array of battery packs 400, as well as energy from the array of battery packs to be converted to AC power and supplement grid power, for the reasons previously described.

FIG. 21B shows another embodiment of the digital electrical routing control system 10 configured for and used to create an AC energy meter and back-up apparatus 365. A solar source is connected to to the distribution panel and tied to the grid via a DC-to-AC inverter. In this embodiment the AC switcher 315 is bi-directional as to support flow of energy in both directions depending on whether local solar source provides more power than the load connected to the panel. In case the grid goes down, power can be maintained to the appliances connected to the panel thanks to the back-up power function of the DC switcher. After a prolonged period of time, the energy battery would run out ultimately. The, digital electrical routing control system 10 can solve that by connecting the DC-to-AC server to the panel and providing a small AC signal to keep the grid-tie-inverter on, and by disconnecting the grid to the panel in order shield the grid from undesired power during possible repairs and to detect when power is restored on the grid. This way the energy from the solar source can be used to power the appliances, and recharge the batteries by alternating the two AC-to-DC converters. The AC switcher can also periodically connect the grid to one of the AC-to-DC converters so the digital electrical routing control system 10 can detect if power on the grid has been restored.

FIG. 21C shows another embodiment of the digital electrical routing control system 10 configured for and used to create an AC energy meter and long-term storage apparatus 368. A solar source can generate significantly more energy during summer than during winter. In contrast, a building can use more energy for heating during in winter than during summer. It is therefore desired to store large amount of energy over a much longer of time than the 15-minute and 24-hour intervals managed by the digital electrical routing control system 10. A storage element 600 can be connected to the system 10 to store larger amount of energy over a larger period of time. The energy storage element 600 can be a compressed-air-energy-storage system or a hydro-pump-storage-system. This additional amount of storage can be managed by a server 500 on the network that manages weather forecast data and can instruct the digital electrical routing control system 10 when to store additional energy and and when to use the long-term stored energy.

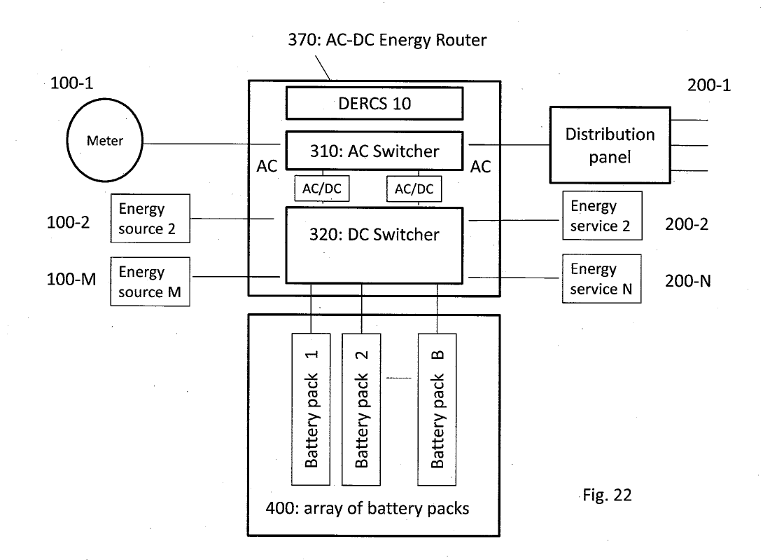

FIG. 22 shows one embodiment of the digital electrical routing control system 10 configured for and used to create an AC-DC energy router 370. The AC-DC energy router apparatus 370 can perform the combined routing functions of the DC energy router 350 and the AC energy meter and power average apparatus 360, and as such, has components from each that are similarly labeled.

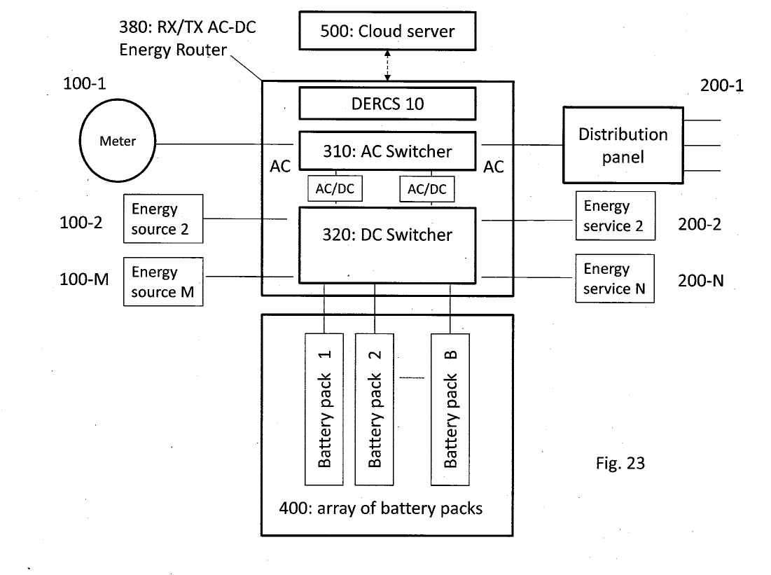

FIG. 23 shows one embodiment of the digital electrical routing control system 10 configured for and used to create an RX/TX AC-DC energy router 380. The RX/TX AC-DC energy router apparatus 380 can perform all of the functions of the AC-DC energy router 370, but is also configured so that the digital electrical routing control system 10 includes a transmit TX block and a receive RX block, thereby allowing communications with an external server, shown as cloud server 500. The digital electrical routing control system 10 can use the communication channel to exchange information with the server such as energy usage, alarms, etc.

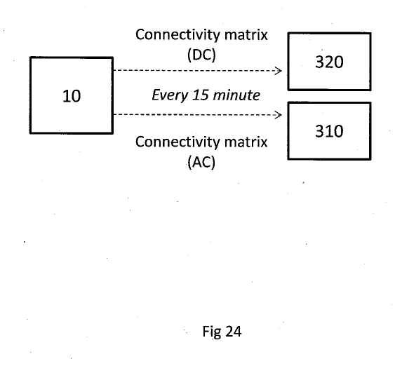

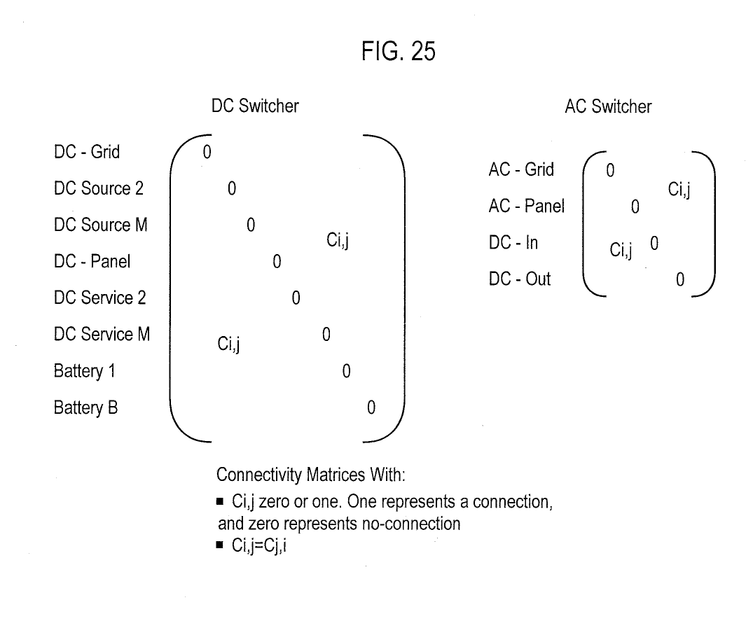

FIG. 24 illustrates control flow at fixed intervals (e.g., 15 minutes), based upon the connectivity matrix of the digital electrical routing control system 10. FIG. 25 illustrates both a DC connectivity matrix for usage with a DC switcher, as well as AC connectivity matrix for usage with an AC switcher with respect to this control flow.

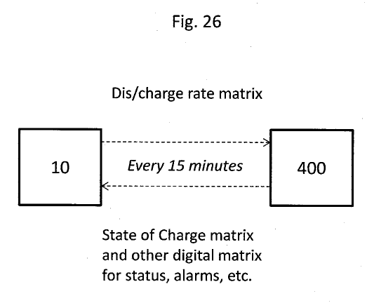

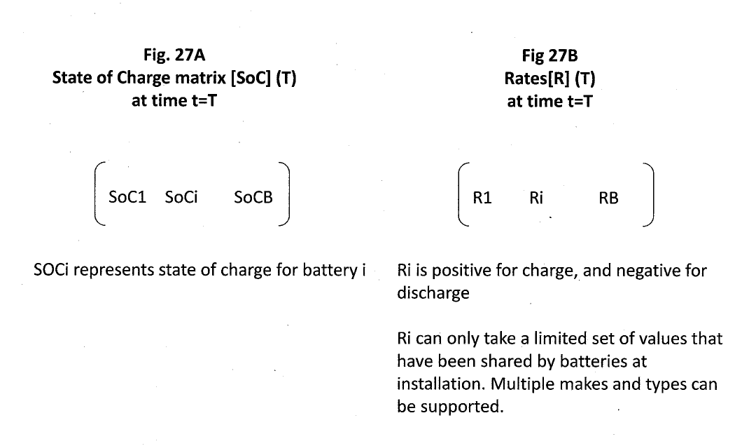

FIG. 26 illustrates control flow at fixed intervals (e.g., 15 minutes) between the digital electrical routing control system 10 and the battery packs in the battery array 400. FIG. 27(a) illustrates the state of charge matrix [SoC] (T). This matrix lists for each time interval T the state of charge of each battery pack in a one dimensional array. FIG. 27(b) illustrates the matrices [R] (T) that sets the rates of charge or discharge for each battery at each time interval T.

FIG. 28-a illustrates the control flow to add a new battery pack to array using the digital electrical routing control system 10. When a new battery pack is inserted, the system 10 information from the battery pack so it can be recognized. The battery pack sends information such as identity information (make, type, etc.) as well as possible charge and discharge rates. After processing the information, the system 10 sends a message to accept or reject the battery pack, and then turns it on or off accordingly. FIG. 28-b illustrates the control flow where the digital electrical routing control system 10 further check the server with new information from the battery pack with the server 500. This can be useful is if the digital electrical routing control system 10 does not recognize the battery pack and is not sure whether to reject or accept the new battery pack.

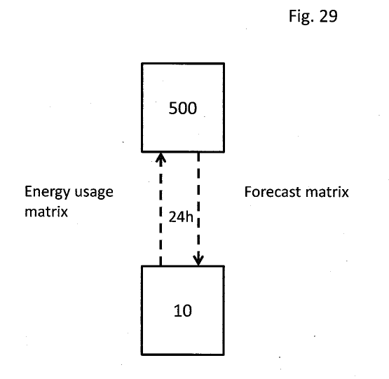

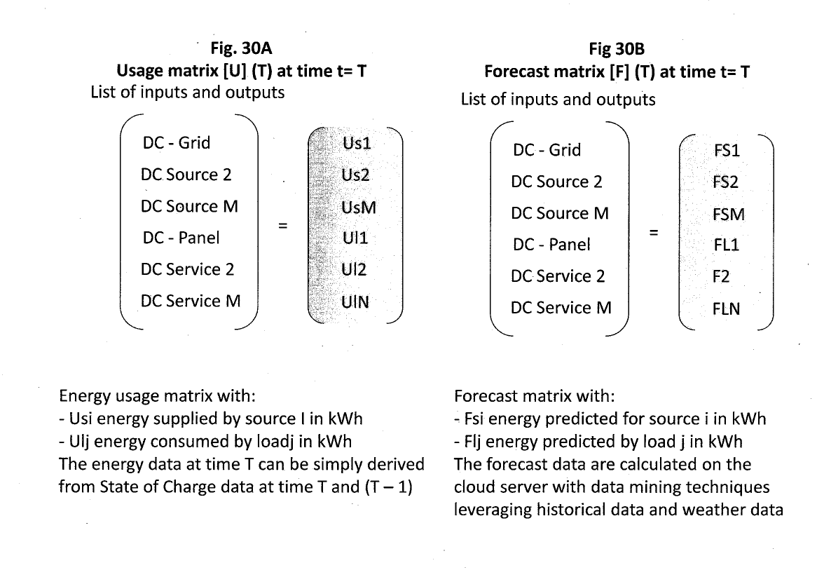

FIG. 29 illustrates the control flow between server 500 and the digital electrical routing control system 10 at regular times (e.g., 24 hours) to retrieve energy usage data and provide forecast data, with FIGS. 30A and 30B illustrating the usage matrix for [U][T] and the forecast matrix [F] [T]. The forecast matrix [F] (T) lists the forecasted values of energy consumed and generated for the various sources and services for each time interval T in the next period of time (e.g., next 24 hours). The usage matrix [U] (T) reports the energy consumed and generated for the previous period of time (e.g., past 24 hours)

With respect to the retrieval of energy usage data and providing forecast data, the following example is instructive:
Example of Residence with two meter lines: one single-phase AC for home, and one for three-phase AC for water pump
The digital electrical routing control system 10 alleviates the need for second line by integrating local renewable energy source (solar panels), and reduces the energy bill by shifting load to off-peak hours
The size of batteries or their lifecycle is optimized by using software algorithms in the digital electrical routing control system 10 for managing the permutation of the switch connectivity matrix and the charge/discharge rate matrix (series of mathematical matrices every 15 minutes)
Cloud server provides forecast data for solar source (weather data mining) and energy load (historical data mining) to Energy router every 24 hours. Cloud server retrieves energy information for reporting, billing, etc. every 24 hours

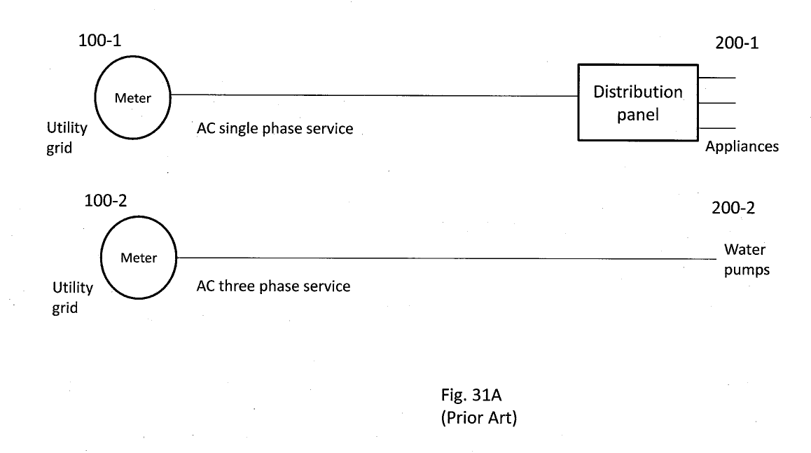

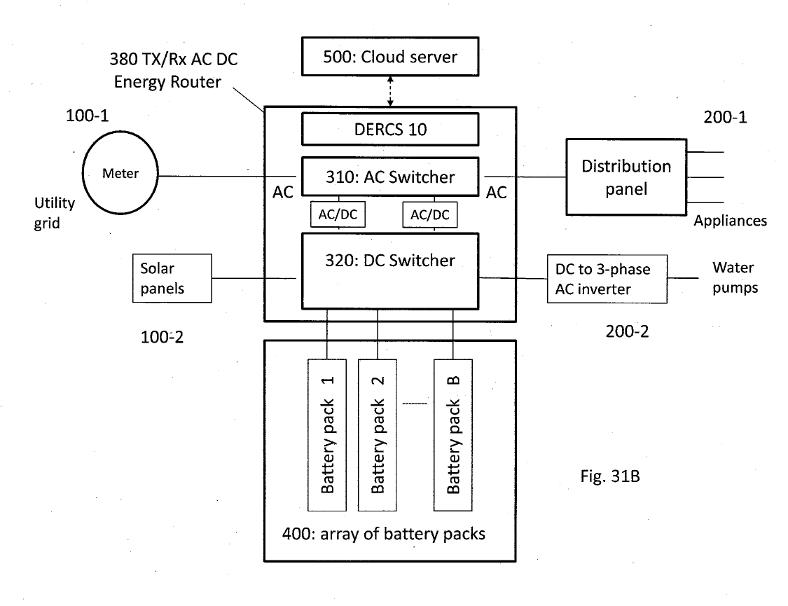

FIG. 31 shows a conventional implementation requiring the usage of 2 different meters 100-1 and 100-2 for a AC single phase and an AC three phase service, taken off of the utility grid. Apparent is the need for two meters, as well as connectivity to the grid at all times for power. FIG. 31 shows a specific implementation of the RX/TX AC-DC energy router 380 previously described with respect to FIG. 23, and shown here in contrast to the FIG. 31 conventional system. Apparent is that such a system can operate with and without grid power, can isolate from the grid, and can provide storage from alternative energy power, among other advantages.

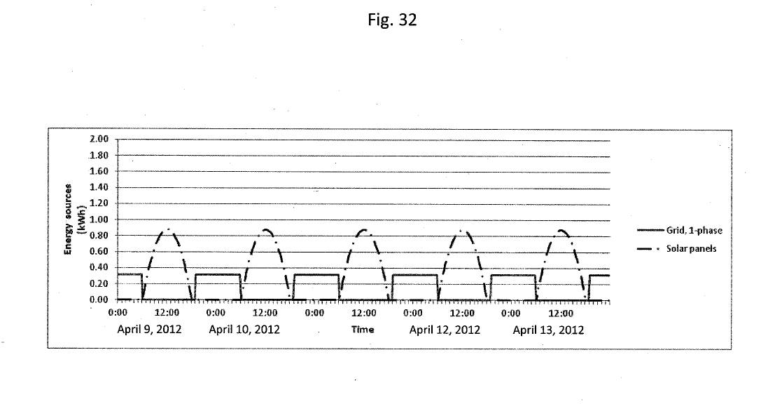

In contrast to FIG. 31 described previously, FIG. 32 shows energy sources to the digital electrical routing control system 10—both grid (flexible) and solar (intermittent). Solar energy is produced at intermittent times (e.g., day light), independently from the control system 10. In contrast the control system 10 can decide when or when not to use energy from the grid, which is available on demand.

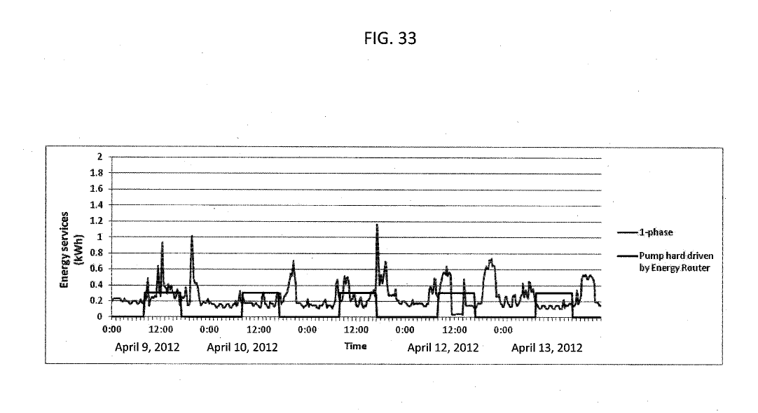

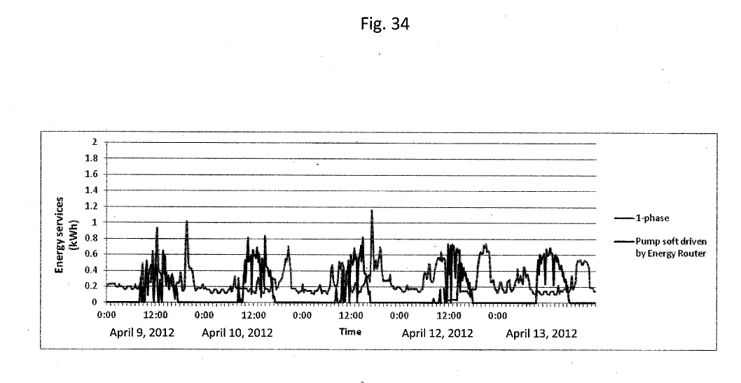

FIG. 33 illustrates energy services provided, where a water pump is hard controlled by the digital electrical routing control system 10. FIG. 34 illustrates energy services provided, where a water pump is soft controlled by the digital electrical routing control system 10. As is apparent, both hard and soft control are possible.

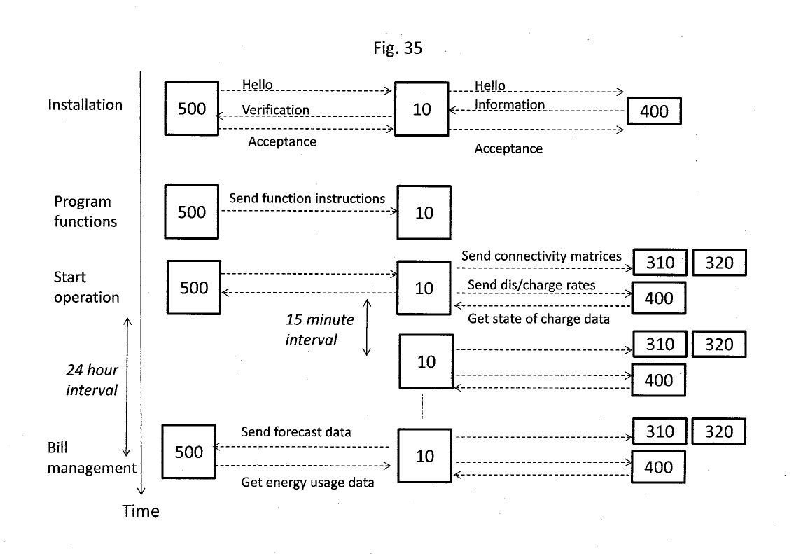

FIG. 35 illustrates a flowchart showing installation, start of operation, connectivity every 15 minutes and bill management every 24 hours, based upon operations of the digital electrical routing control system 10.

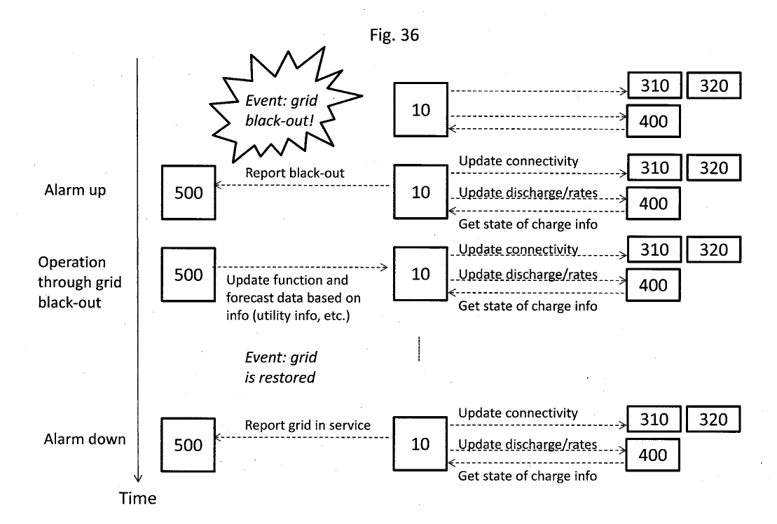

FIG. 36 illustrates a flowchart showing digital electrical routing control system 10 responding to grid black-out (an event at the location of the digital electrical routing control system 10).

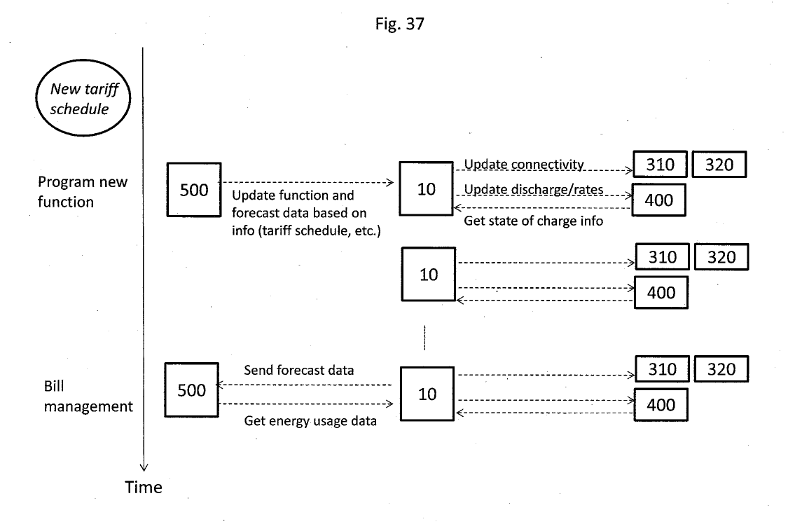

FIG. 37 illustrates a flowchart showing cloud server 500 responding to a public change in utility tariff structure (change in peak hours or else), which triggers cloud server 500 to program new functions on the digital electrical routing control system 10 to save money, etc. This causes digital electrical routing control system 10 to update its connectivity matrix to update when to charge from what source and possibly change when to drive flexible loads.

### Peer-to-Peer Transaction and Mobile Energy Service

Improvements to the electrical power grid management techniques to provide a way to transact energy among peer customer sites, in particular to a mobile energy service without affecting the grid will now be described.

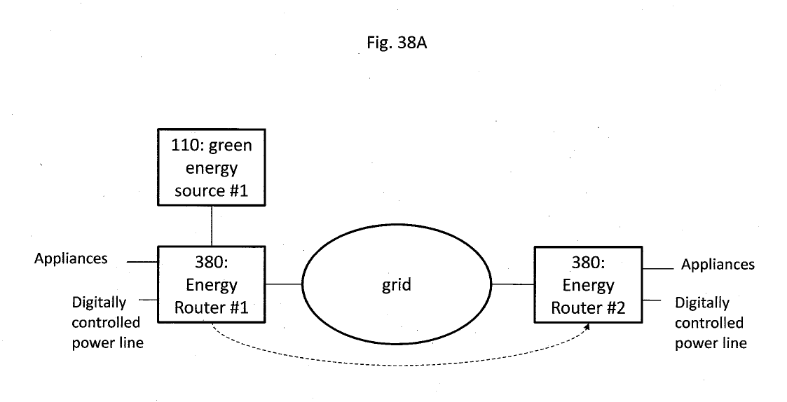

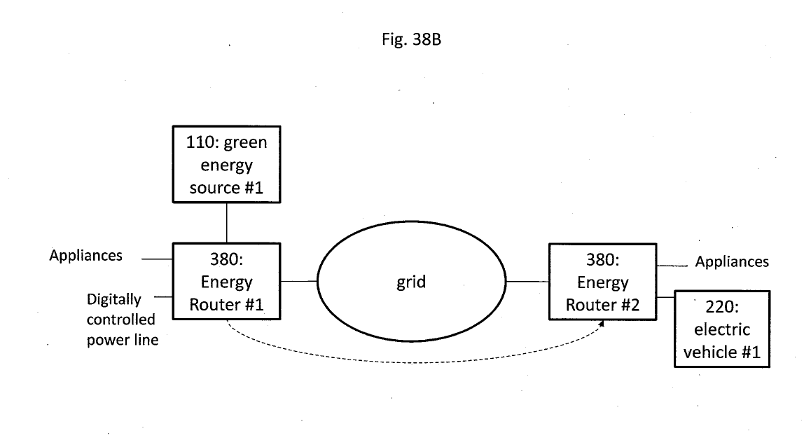

FIG. 38A illustrates one embodiment where two energy routers 380 exchange energy without affecting a grid. The energy router #1 (ER#1) and energy router (ER#2) coordinate via a server 500 the time to discharge energy and to charge energy on the grid the net additional power variation added to the grid is zero. The energy from ER#1 used to compensate higher consumption at ER#2 can be guaranteed to come from renewable source of energy (“green”). This provides a method to exchange energy of specific property line clean energy among peers over a grid. Peers may be residential or commercial facility owners who want to integrate more renewable energy than grid can do.

FIG. 38B illustrated another embodiment where the peer-to-peer energy transaction technique is used to provide a mobile service to an Electric Vehicle (EV#1) that belongs to the account holder of ER#1. In the case EV#1 is connected to peer site ER#2, EV#1 can be charged with green energy transacted from ER#1. The host of ER#2 is not charged for the additional energy consumption, the driver EV#1 uses clean energy to power the vehicle, and the grid is not penalized with a peak in power load. Compared to the peer-to-peer energy exchange described above, the mobile energy service comes with an added complexity. The energy account is moving across multiple locations so the host site must first recognize the vehicle (EV#1) and its associated account (ER#1) before establishing the exchange of energy. The account tracking can be performed by a central server 500 that managed the energy routers 380.

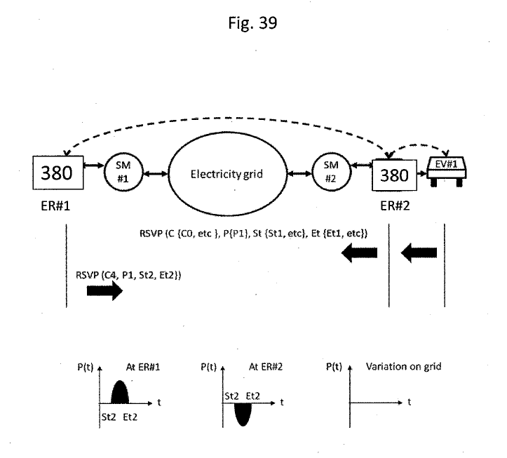

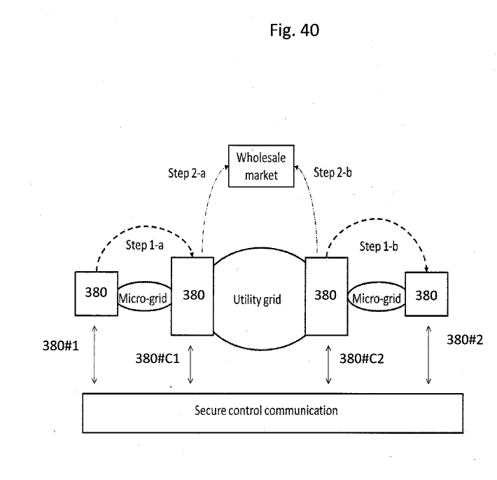

FIG. 39 illustrates the flow chart of commands to coordinate the charge and discharge events of power on the grid over a period of time. Reservation protocols such as RSVP and variations thereof can be used to set and confirm the transaction.

Utilities today provide electricity to residential, commercial or industrial customers in exchange of a monthly bill. The account is physically associated with a meter at a specific geographic location. If a customer charges an Electric Vehicle at another location, the other customer at that location is billed for the energy usage. Moreover, utilities today do not accept to exchange energy among meter accounts, and do not act as a broker in the case customers would like to trade energy surplus at their location if they have local sources of energy such as solar panels. In particular, current regulation often prohibits customers, or third-party aggregators, to put energy on the grid below a high threshold (e.g., 500 kW in California).

As discussed above previously, most solar or wind power installations are tied to the grid. When the load of a building is less than what the solar or wind source provides at any given time, the grid absorbs the surplus of energy. If the load is higher, then the grid provides the additional energy. The utility keeps track of the consumption and production at customer premises using net metering. This effectively allows the customer and the utility to exchange energy between them, but not among customers. As the level of renewable energy increases, this can cause instability on the grid or even black-outs. As a result, utilities limit the amount of renewable energy per meter (e.g., 1MW for PG&E) and net metering is capped by a percentage of peak demand (e.g., 5%). Customers are not allowed use renewable energy to their daily consumption beyond those limits, to charge electric vehicles or water pumps for instance.

While the peer-to-peer energy transaction service may potentially have wide application, due to regulatory limits, it is immediately practicable in local micro-grid environments such as a University campus or a Military base that operate their own local grid, since most utilities today do not allow third-party aggregators to put energy back in the distribution grid.

In FIG. 40 the peer-to-peer energy transaction technique leverages wholesale markets to extend the service across local grids connected by a utility grid that does not support peer-to-peer energy transactions such as the ones described above. This is accomplished by separating the exchange of physical electricity from the financial transaction. This allows micro-grids to function independently from utility distribution grids and extends the notion of energy exchange to energy credits that can be sold at a later time or traded as a virtual good within a community. Security of the transactions can be provided by an existing Virtual Private Network in the case of businesses or by secured mobile payment techniques for consumers.

The extended peer-to-peer energy transaction technique described herein is designed to alleviate the limitations above using aggregation appliances referred as energy routers previously, such as the energy routers 350, 365, 370 and 380. This mobile energy service is enabled to exchange energy using energy off-sets among locations so that the grid is not affected by the transaction.

To extend the concept of energy exchange to other locations outside the local micro-grid, the exchange of physical energy and the financial transaction can be separated in two steps in order not to affect the utility grid. Let's take the example above of a customer owning an energy router 380#1 (though other embodiments of energy routers, not just 380, could be used), who is traveling at another location with an EV (EV#1). The driver plugs the car to an energy router 3 80#2 that is located in another micro-grid. They agree to exchange energy via the communication control, which can be triggered by a phone application for instance. Energy router 380#2 provides the electricity for the recharge of EV#1, and it draws energy from a local core router 380#C2 that is connected to the utility grid and has a capacity to participate in wholesale markets (e.g., 500 kW capacity in California). Core Router 380#C2 debits the account of energy router 380#1 and not energy router 380#2, and communicates with the core router 380#C1 connected to energy router 380#1 in the other microgrid (CR#1). As a result, core router 380#C1 takes energy from energy router 380#1. The energy exchange within the separate micro-grids is represented in FIG. 38, which illustrates a mobile energy service allowing an owner of Electric Vehicle (EV#1) to charge at another customer location (energy router 380#2) using its account (energy router 380#1). The energy exchange between energy router 380#1 and core router 380#C1 (step 1-a) and energy router 380#2 and core router 380#C2 (step 1-b) can happen at the same time or not.

Because no exchange of energy between the Core Routers is required at the time of the financial transaction between energy router 380#1 and energy router 380#2, the energy transaction can occur. However, core router 380#C1 and core router 380#C2 are left with a positive and negative balance of energy respectively. This can be solved by having Core Routers participate to whole-sale markets, core router 380#C1 can sell the surplus energy on the market as part of a larger energy transaction (step 2-a), and compensate core router 380#C2 financially for the share of energy surplus (value of step 2-a). In another embodiment, core router 380#C2 sells the lack of energy if wholesale markets have a regulation market that values additional load (step 2-b). core router 380#C1 then compensates core router 380#C2 for the difference between the two transactions above (value of step 2-a minus value of step 2-b). The settling of balances between Core Routers is represented in FIG. 39.

The mechanism described above can also be used among energy routers to exchange surplus of renewable energy. In the case the customer at energy router 380#1 has a surplus of energy, and the customer at energy router 380#2 has a need for energy for its own consumption, they can use the two step process described previously. The Core Routers keep track of credits and debits of the energy router in their respective micro-grids, and regularly settle balances among them when it is desirable for the grid regulator.

One common issue brought by energy transaction is the new threat of cyber attacks that could affect the electricity service at a customer location. If customer 1 and customer 2 are businesses, they can use their existing IP routers to provide a secure communication line among them. One such secure common router is a Cisco 3800. The energy exchange service is another secured communication like banking, video conferencing, etc. In one embodiment, the computer of the ER's is connected via wireless Ethernet to the secure IP routers. Encryption is used to protect the wireless connections.

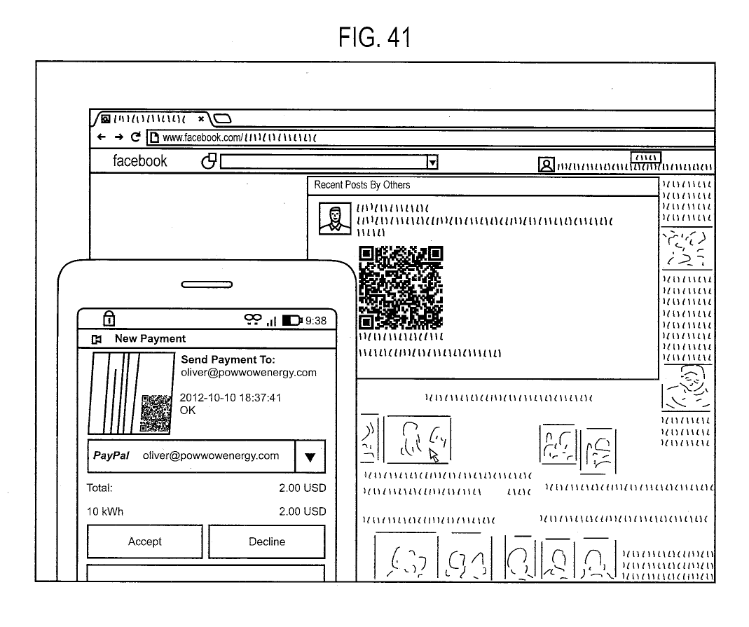

In another embodiment, the computer of the ER's is connected via wire-line Ethernet to the secure IP routers, as shown in FIG. 41 that illustrates an exchange of energy using a secure mobile payment application where the green energy for sale (10 kWh) is represented by a QR code with a time limit The energy coupon can be advertised via social network like a Facebook page in this case.

In another embodiment, the computer engine of the ER is part of a card that first within a slot of the IP router.

If customer 1 and customer 2 are general consumers, they can use secure Internet or mobile payment techniques. In particular, customer can generate QR codes to represent the available energy credit they would like to exchange, as described in PCT/US2011/027793, the contents of which are expressly incorporated by reference herein. Customer 2 can scan the energy credit displayed on a social network (picture 3) with its phone, and accept the transaction. Once confirmed, the energy exchange between ER#1 and ER#2 can occur as described above.

Although the embodiments have particularly described above, it should be readily apparent to those of ordinary skill in the art that various changes, modifications and substitutes are intended within the form and details thereof, without departing from their spirit and scope. Accordingly, it will be appreciated that in numerous instances some features will be employed without a corresponding use of other features. Further, those skilled in the art will understand that variations can be made in the number and arrangement of components illustrated in the above figures.

What is claimed is:

1. A method of determining an amount of energy used by a load using a computer, with the energy being provided from a first battery and a second battery, and with other energy being supplied to charge the first battery and the second battery, the method comprising the steps of:
initiating, using the computer, charging of the first battery with the other energy while the second battery is being drained by connection to the load;
initiating, using the computer, charging of the second battery with the other energy while the first battery is being drained by connection to the load; and
detecting, using the computer, an amount of energy consumed during an interval of time based upon an amount of charging of the first battery and the second battery during the interval of time.

2. The method according to claim 1, wherein:
the step of charging the first battery with the other energy includes the steps of:
providing a first start charging digital signal from the computer to begin a first charging interval and activate a first switch to cause the other energy to charge the first battery;
providing a first stop charging digital signal from the computer to end the first charging interval;
providing a second start charging digital signal from the computer to begin a second charging interval and activate a second switch to cause the other energy to charge the second battery, the second start charging digital signal occurring only after the end of the first charging interval;
providing a second stop charging digital signal from the computer to end the second charging interval; and
repeating each of the providing steps in sequence a plurality of times to provide continuous charging and continuous connection to the load.

3. The method according to claim 1 wherein the other energy is provided by an intermittent energy source.

4. The method according to claim 1, wherein the load is a variable load, and wherein harmonics generated by the variable load are isolated from the energy source by the first battery and the second battery

5. An apparatus for routing energy from a DC energy source to a load, using an array of batteries that include at least a first battery and a second battery, the apparatus comprising:
a DC switch, the DC switch including:
a DC input ;
a DC output;
a plurality of DC charging inputs/outputs for connection to the array of batteries, including the first battery and the second battery; and
a DC switch matrix for selectively coupling between the DC input, the DC output, and the plurality of DC charging inputs/outputs; and
a controller that includes a processor and software executable by the processor, the controller controlling a DC switch matrix state, thereby permitting:
charging of the first battery while the second battery is being drained by connection to the load; and
charging of the second battery while the first battery is being drained by connection to the load.

6. The apparatus according to claim 5 wherein:
the controller further detects an amount of energy consumed during an interval of time based upon the state of charge of the discharging battery at the start and the end of the interval of time; and
the controller further detects an amount of energy provided during an interval of time based upon the state of charge of the charging battery at the start and the interval of time.

7. An apparatus for routing energy from an AC energy source to at least one load, using an array of batteries that include at least a first battery and a second battery, the apparatus comprising:
a DC switch, the DC switch including:
a DC input ;
a DC output;
an AC to DC converter input/output;
a DC/AC converter input/output;
a plurality of DC charging inputs/outputs for connection to the array of batteries, including the first battery and the second battery; and
a DC switch matrix for selectively coupling between the DC input, the DC output, the AC to DC converter input/output, the DC/AC converter input/output, and the plurality of DC charging inputs/outputs;
an AC switch, the AC switch including:
an AC input;
an AC output;
an AC to DC converter for converting alternating current to direct current;
a DC to AC converter for converting direct current to alternating current; and
an AC switch matrix selectively coupling between the AC input, the AC output, the AC to DC converter, and the DC to AC converter; and
a controller that includes a processor and software executable by the processor, the controller controlling a DC switch matrix state and an AC switch matrix, thereby permitting:
charging of the first battery while the second battery is being drained by connection to the load;
charging of the second battery while the first battery is being drained by connection to the load; and
wherein the controller further detects an amount of energy consumed during an interval of time based upon the state of charge of the discharging battery at the start and the end of the interval of time; and
wherein the controller further detects an amount of energy provided during an interval of time based upon the state of charge of the charging battery at the start and the interval of time.
